(19) United States
(12) Patent Application Publication
(10) Pub. No.: US 2020/0388462 A1
(43) Pub. Date: Dec. 10, 2020

(54) SYSTEMS AND METHODS FOR TUNING AND CALIBRATING CHARGED PARTICLE BEAM APPARATUS

(71) Applicant: ASML Netherlands B.V., Veldhoven (NL)

(72) Inventors: Van-Duc NGUYEN, Pleasanton, CA (US); Xiong XIAO, San Jose, CA (US); Dongdong WU, San Jose, CA (US); Chi Michael MAI, Fremont, CA (US); Chien-Hung CHOU, San Jose, CA (US)

(21) Appl. No.: 16/770,513

(22) PCT Filed: Dec. 4, 2018
(86) PCT No.: PCT/EP2018/083452

§ 371 Date: Jun. 5, 2020

Related U.S. Application Data
(60) Provisional application No. 62/595,039, filed on Dec. 5, 2017.

(51) Int. Cl. H01J 37/22

(52) U.S. Cl. CPC H01J 37/222; H01J 37/28

(57) ABSTRACT

Systems and methods for tuning and/or calibrating a charged particle beam apparatus are disclosed. According to certain embodiments, a reference specimen comprises a substrate having a plurality of first objects at a first pitch, and a plurality of second objects at a second pitch. Regions containing the first and second objects may overlap. A method of tuning and/or calibrating may comprise analyzing an image of a sample at a plurality of coarseness levels, determining whether a parameter of the image satisfies a criteria based on measured characteristics of the image at the coarseness levels, and adjusting the parameter.

### CROSS-REFERENCE TO RELATED APPLICATIONS

This application claims priority of U.S. application 62/595,039 which was filed on Dec. 5, 2017 and which is incorporated herein in its entirety by reference.

### TECHNICAL FIELD

The present disclosure generally relates to the fields of imaging using charged particle beam or optical apparatuses, and more particularly, to systems and methods for tuning and calibrating a charged particle beam apparatus.

### BACKGROUND

Tuning and calibration are important for measuring devices to ensure accuracy. In electron microscopy, a reference specimen may be used for imaging calibration and tuning. The reference specimen should be provided with high accuracy, repeatability, and uniformity.

Some methods for tuning may comprise, for example, tuning a measuring device such as a scanning electron microscope (SEM), from large initial error. Typically, very large features are observed first. Then, the field of view (FOV) is shifted to regions where smaller features are present. A calibration method may employ a laser interferometer with a reference specimen having a known geometry. For example, a target object on a reference specimen may be a plurality of lines, such as a series of parallel ribs running across the surface of the sample. Lines may provide good image contrast because edges are readily discernible. A laser interferometer system may be coupled to the sample stage and may report the position of the sample, or control the motion of the sample stage with high accuracy. In a calibration method, an SEM image coordinate system can be calibrated against a laser interferometer by moving a known target object by a known distance. This method starts with a large and unique object for rough calibration to establish a coordinate baseline, and then moves to regions of progressively denser objects to get the most repeatable calibration. A larger object is easier to match uniquely, but has poor location repeatability. To obtain better repeatability, many step edges are required, so a reference specimen should be provided with some regions having many densely arranged objects.

Drawbacks of conventional tuning and calibration procedures may include, for example, poor efficiency, low robustness, risk of sample damage and the undesired accumulation of surface charge. SEM instruments suffer from limited range in tuning, for example, having a small convergence region. Furthermore, when the sample comprises an electron-sensitive material, excessive scanning can damage the sample. In some cases, a large electron dose can ruin the surface to be inspected, such as gates that constitute the pattern on the wafer.

Moreover, conventional tuning and calibration methods are ill-suited to multi-beam inspection (MBI) systems. For example, in an MBI system comprising a plurality of beamlets directed to a sample surface, it is difficult to synchronize among different beams and move the sample inspection area to corresponding regions of different pattern scales. With multiple beamlets, it may be difficult or impossible to observe the same unique objects for all beamlets, and moving the sample stage to view the objects requires a high degree of coordination. Matching a sparse pattern having unique objects may yield low repeatability, while matching a dense pattern may yield confusion because of the abundance of replicated patterns. Coarse-to-fine calibration may require using many different regions of objects to obtain both accuracy and repeatability.

Furthermore, an MBI system may require frequent re-tuning and re-calibration in some applications. Searching using a typical reference specimen is less redundant, less robust, and slow. Tuning and calibration should be robust, minimize the number of images used, and should be fast in order to increase throughput. An improved tuning method is therefore desired.

### SUMMARY

Embodiments of the present disclosure provide systems and methods for tuning and/or calibration of a charged particle apparatus. In one embodiment, a reference pattern is provided. The reference pattern may comprise an arrangement of dots and grids.

Some embodiments relate to a calibration standard. In some embodiments, a reference standard includes a planar substrate. The substrate may include a plurality of first objects having a first size and being located in a first region on the substrate spaced at a first period, and a plurality of second objects having a second size and being located in a second region on the substrate spaced at a second period. The first size may be smaller than the second size. The first period may be smaller than the second period. The first region and the second region may overlap.

Some embodiments relate to a method. In some embodiments, a method for adjusting a charged particle beam may include analyzing an image of a sample at a plurality of coarseness levels, the image containing a plurality of first objects having a first feature size and a plurality of second objects having a second feature size, determining whether a parameter of the image satisfies a criteria based on measured characteristics of the image at the coarseness levels, and adjusting the parameter based on a result of the determining. The determining may include determining whether a parameter of the image satisfies a predetermined criteria based on a first measured characteristic of the image at a first coarseness level of the plurality of coarseness levels, and determining whether the parameter of the image satisfies a predetermined criteria based on a second measured characteristic of the image at a second coarseness level of the plurality of coarseness levels.

Some objects and advantages of the disclosed embodiments will be set forth in part in the following description, and in part will be apparent from the description, or may be learned by practice of the embodiments. Objects and advantages of the disclosed embodiments may be realized and attained by the elements and combinations set forth in the claims. However, exemplary embodiments of the present disclosure are not necessarily required to achieve such exemplary objects and advantages, and some embodiments may not achieve any of the stated objects and advantages.

It is to be understood that both the foregoing general description and the following detailed description are exemplary and explanatory only and are not restrictive of the disclosed embodiments, as claimed.

### BRIEF DESCRIPTION OF THE DRAWINGS

FIGS. 1A and 1B are diagrams illustrating samples and artifacts used as a reference specimen.

FIG. 2 is a schematic diagram illustrating an exemplary electron beam inspection (EBI) system, consistent with embodiments of the present disclosure.

FIG. 3 is a diagram illustrating a multi-beam electron beam tool that can be a part of the exemplary electron beam inspection system of FIG. 2, consistent with embodiments of the present disclosure.

FIG. 4 is a diagram illustrating a single-beam electron beam tool that can be a part of the exemplary electron beam inspection system of FIG. 2, consistent with embodiments of the present disclosure.

FIGS. 5A and 5B are diagrams illustrating designs of a reference specimen, consistent with embodiments of the present disclosure.

FIG. 6 is a detailed view of a design of a reference specimen, consistent with embodiments of the present disclosure.

FIG. 7 is a diagram illustrating exemplary reference objects, consistent with embodiments of the present disclosure.

FIG. 8 is a diagram illustrating a design of a reference specimen with cross-shaped objects, consistent with embodiments of the present disclosure.

FIGS. 9A and 9B are diagrams illustrating designs of reference specimens, consistent with embodiments of the present disclosure.

FIG. 10 is a graph illustrating tuning performance of reference specimens, consistent with embodiments of the present disclosure.

FIGS. 11A and 11B are flow charts of exemplary calibration and tuning methods, consistent with embodiments of the present disclosure.

### DESCRIPTION OF EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems and methods consistent with aspects related to the subject matter as recited in the appended claims.

Embodiments of the present disclosure provide a pattern for tuning and/or calibration. In some embodiments, tuning may refer to methods for maximizing the resolution of an imaging system. Calibration may refer to methods for establishing a coordinate system. Calibration may comprise aligning axes of the coordinate system with the sample to be inspected.

Tuning may progress beginning with large shapes on a reference specimen, since small shapes will blur and blend into each other resulting in a blank image with no sharpness measurement being possible. Then, the inspection area must be shifted by, for example, moving the specimen via a sample stage to a different region having small shapes to obtain precision. Tuning may start from a region of large shapes for roughly establishing a baseline, then moves to progressively smaller and denser regions of small shapes. To get the highest precision, this progression must continue to very small objects.

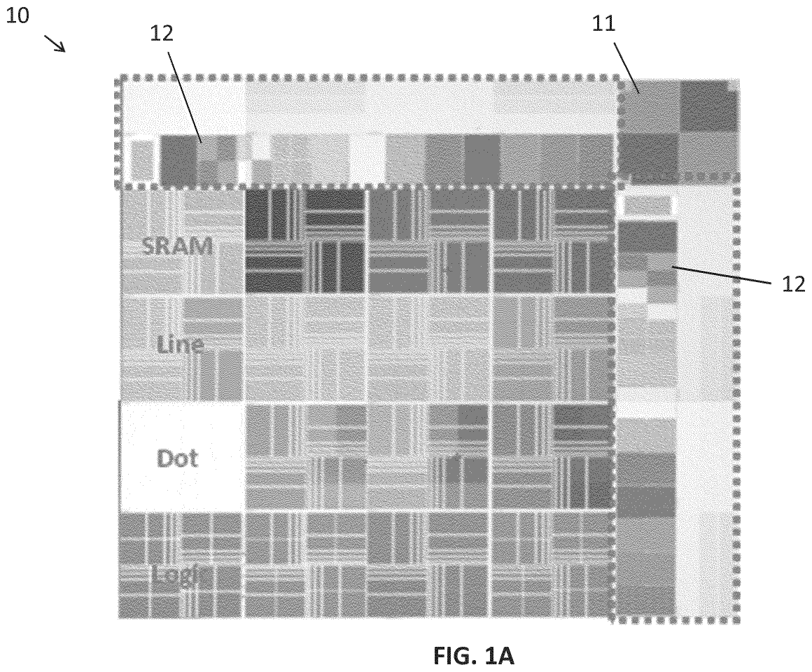

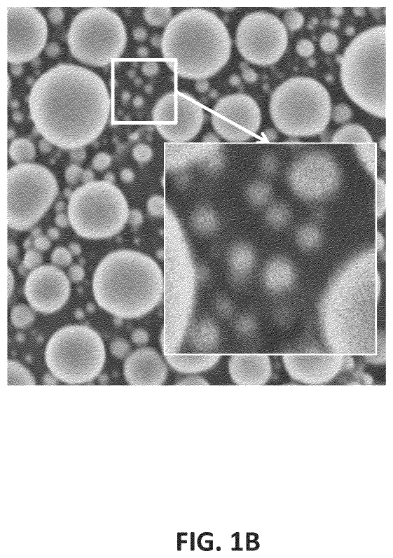

A reference specimen for SEM may comprise multiple separate regions of different shapes and sizes that are etched on a wafer with a flat surface. For example, FIG. 1A shows an artifact 10 having a first region 11 with relatively large shapes, and a second region 12 with relatively small shapes. Second region 12 may comprise many small objects that have a small pattern pitch (that is, small object width and small spacing between adjacent objects). Second region 12 may be required to reach an ultra-precise stopping point. Using artifact 10, many stage moves are required to arrive at the various regions for imaging.

An alternative artifact may comprise a flat surface coated with tin spheres to yield a random variation of different sized objects, as in FIG. 1B. However, such a coated surface is not flat, and thus not all pixels in an imaging region will be inside the depth of focus.

Thus, tuning and calibrating an SEM using artifact 10 or tin spheres may be laborious, and can damage surface of sample, since many imaging scans are required. For example, in order to image all areas in the proper focal region and/or in the multiple regions with the various different sized objects, many imaging scans are performed on the sample, depositing a large amount of charge on the sample surface.

In some embodiments, a reference standard may be provided including a pattern that comprises a region containing a plurality of different sized dots. A dot may refer to an object on a surface of a sample that can be used as a target for conducting imaging tuning and/or calibration. While, in some instances, a dot may have a shape such as a small round mark, embodiments of the present disclosure are not so limited. It shall be appreciated that a dot may have a variety of shapes.

A pattern comprising a plurality of dots may be used as a reference standard for tuning and/or calibrating a charged particle beam apparatus so as to generate responses at a plurality of frequencies. For example, a transform function may have responses at a plurality of frequency levels based on image analysis of the pattern. An exemplary method may comprise conducting a search from coarse to fine that maximizes total image sharpness. The coarse region may correspond to low frequencies, and the fine region may correspond to high frequencies. The method may comprise summing all frequency levels of signals detected from the pattern.

For example, the pattern may comprise a plurality of first objects having a first pitch. The pitch of the first objects may correspond to the size of the first objects and/or a period at which adjacent first objects are spaced apart from one another. The first objects may be uniform. The pattern may also comprise a plurality of second objects having a second pitch. When analyzed with a transform function, such as the Fast Fourier Transform (FFT) or wavelet transform (WT), image data may have a plurality of responses at different frequencies. Signals generated at each of the different frequencies may correspond to the different sized objects.

Some embodiments may provide a non-transitory computer-readable medium storing a set of instructions that are executable by at least one processor of an apparatus to cause the apparatus to perform a tuning method. The apparatus may be a charged particle beam apparatus, such as a scanning electron microscope. The charged particle beam apparatus may comprise a controller that is configured to control operations of the charged particle beam apparatus. The tuning method may be implemented through a software program of the controller. A sample comprising a reference standard can be loaded into the charged particle beam apparatus and used to tune the charged particle beam apparatus. When the charged particle beam apparatus comprises multiple beams directed to the sample, an exemplary tuning method may use the reference standard comprising a plurality of dots and the computer-readable medium to robustly tune the multiple beams at the same time, independently from each other. Some embodiments may eliminate the need to move the sample from regions containing large objects to regions containing progressively smaller objects. Thus, some embodiments may result in a robust search that utilizes a minimal number of images.

In some embodiments, a reference standard comprises a pattern with one region containing a plurality of different sized grids. A grid may be a group of dots ordered in a predetermined arrangement. The pattern may contain dots spaced by relatively small periods. Because the grids may be etched from a mask with globally accurate scaling, a tuning and/or calibration method may comprise comparing an image coordinate system over a large field of view to a designed grid coordinate system, and adjusting correction parameters until the observed image coordinate system and the designed grid coordinate system match. Matching may comprise determining a degree of correlation. Determination of a match may be based on whether a determined degree of correlation is greater than or equal to a predetermined threshold value.

Matching can be conducted using a plurality of edges taken along one axis at a time. For example, a plurality of object edges can be observed along a desired axis using one-dimensional (1D) correlation. Using 1D correlation, a high signal to noise (S/N) ratio can be achieved. Moreover, calibration can be achieved that is robust to local etching errors and global noise. For example, in an SEM system, global noise may be relatively high and thus, a robust calibration method is desired. Sparser grids of larger dots may also be used as a ruler to find offsets between separate beams of a multiple beam system.

When a plurality of different sized objects are arranged in the same region, both fine-tuning for high resolution, and accurate coordinate system determination can be achieved at the same location. In some applications, charged particle beam systems may perform tuning and calibration before conducting charged particle beam inspection. Tuning and calibration are desired where the effects of system drift and random drift can be avoided.

A variety of shapes can be obtained and used in a pattern for a reference standard for various purposes. For example, round shapes can be used for obtaining directional sharpness. When it is desired to tune a beam shape to a perfect circle, dots having a round shape can be used. In some embodiments, an etching process can be used such that the four corners of square dots are rounded. For example, a mask design may comprise square shapes; however, due to etching process limits, resulting shapes from square designs may comprise objects with rounded corners. Thus, the resulting formed objects may have substantially circular shaped features. The objects may be the smallest square patterns of a mask design.

Shapes of objects may be based on a graphic database system (GDS) plan of a pattern. A mask can be designed with GDS, for example, and used for etching.

Objects can be formed with shapes comprising rectangular features. For example, even when a square base shape comprises rounded corners, the shape may have a linear edge. When objects have edges, step edge response can be measured.

Step edge response can be measured at a plurality of scales. For example, an SEM image can be obtained that comprises many different sized dots. Image processing can be performed on the obtained image. Thereafter, step edge response can be measured at different scales from a 1-wavelet transform of the image data.

A tuning method may comprise software for searching for max sharpness from coarse to fine scales.

Square shapes may allow for image acquisition with increased S/N. For example, when projecting many contiguous rows or columns into a profile along an x- or y-axis, a semi-continuous edge may be produced. Etching irregularities and SEM noise may be averaged out. For example, noise may be reduced by 1/sqrt(n) where n is the number of independent objects along the projection direction.

Projection profiles can be analyzed based on, for example, 1D correlation. Analysis based on 1D correlation may be relatively fast. Furthermore, 1D correlation of projection profiles can be used to measure 2×2 linear coordinate transforms, and two offsets can be used instead of performing a two-dimensional (2D) correlation of an object with image windows.

Precision of 1D correlation may depend more on the presence of step edges matching at periodic grid locations, and less on the grey level variation of projection profiles because of the different dot sizes.

Reference will now be made in detail to some exemplary embodiments that are illustrated in the accompanying drawings. Although the following embodiments are described in the context of utilizing electron beams, the present disclosure is not so limited. Other types of charged particle beams can be similarly applied. Furthermore, systems and methods consistent with aspects of the present disclosure may be applicable in environments for optical imaging.

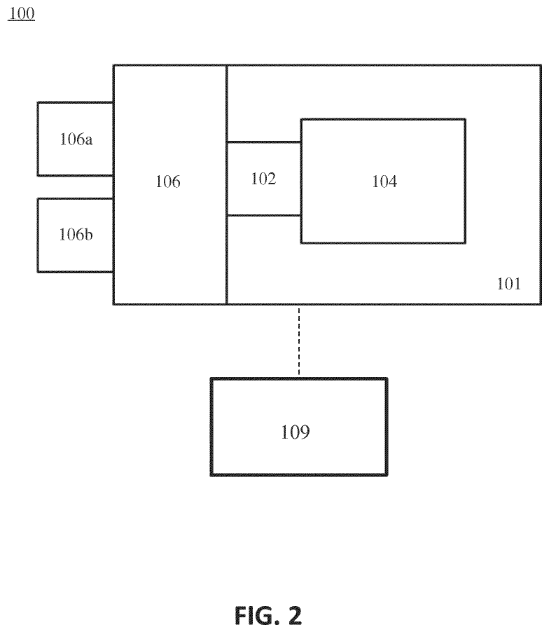

Reference is now made to FIG. 2, which illustrates an exemplary electron beam inspection (EBI) system 100 consistent with embodiments of the present disclosure. As shown in FIG. 2, EBI system 100 includes a main chamber 101 a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be collectively referred to as “wafers” hereafter).

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 can part of the structure.

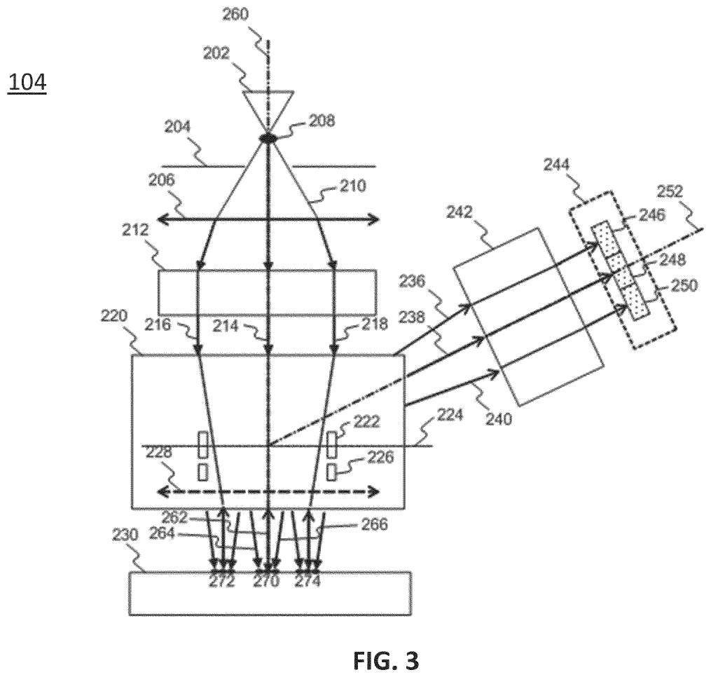

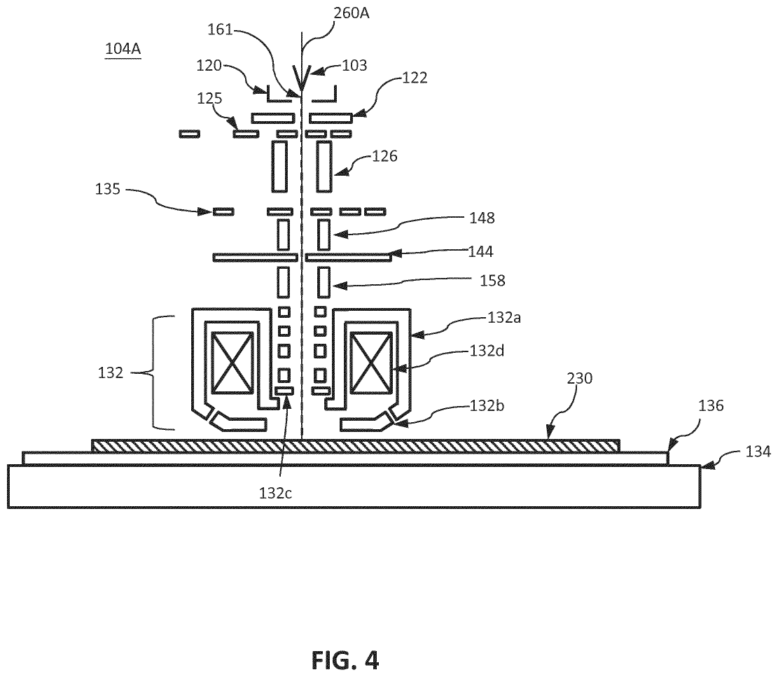

FIG. 3 illustrates an electron beam tool 104 that may be configured for use in EBI system 100. Electron beam tool 104 may be a multi-beam apparatus, as shown in FIG. 3, or a single beam apparatus, as shown in FIG. 4.

FIG. 3 illustrates an electron beam tool 104 (also referred to herein as apparatus 104) that may be configured for use in a multi-beam imaging (MBI) system. Electron beam tool 104 comprises an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 3), multiple secondary electron beams 236, 238, and 240, a secondary optical system 242, and an electron detection device 244. Primary projection optical system 220 can comprise a beam separator 222, deflection scanning unit 226, and objective lens 228. Electron detection device 244 can comprise detection sub-regions 246, 248, and 250.

Electron source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and electron detection device 244 can be aligned with a secondary optical axis 252 of apparatus 104.

Electron source 202 can comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 can block off peripheral electrons of primary electron beam 210 to reduce Coulomb effect. The Coulomb effect may cause an increase in size of probe spots.

Source conversion unit 212 can comprise an array of image-forming elements (not shown in FIG. 3) and an array of beam-limit apertures (not shown in FIG. 3). The array of image-forming elements can comprise an array of micro-deflectors or micro-lenses. The array of image-forming elements can form a plurality of parallel images (virtual or real) of crossover 208 with a plurality of beamlets 214, 216, and 218 of primary electron beam 210. The array of beam-limit apertures can limit the plurality of beamlets 214, 216, and 218. While three beamlets 214, 216, and 218 are shown in FIG. 3, embodiments of the present disclosure are not so limited. For example, in some embodiments, an apparatus 104 may be configured to generate a first number of beamlets. In some embodiments, the first number of beamlets may be in a range (endpoints inclusive) from 1 to 1000. In some embodiments, the first number of beamlets may be in a range from 9 to 500. In an exemplary embodiment, an apparatus 104 may generate 9 beamlets.

Condenser lens 206 can focus primary electron beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on surface of wafer 230.

Beam separator 222 can be a beam separator of Wien filter type generating an electrostatic dipole field and a magnetic dipole field. In some embodiments, if they are applied, the force exerted by electrostatic dipole field on an electron of beamlets 214, 216, and 218 can be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 can also be non-zero. Beam separator 222 can separate secondary electron beams 236, 238, and 240 from beamlets 214, 216, and 218 and direct secondary electron beams 236, 238, and 240 towards secondary optical system 242.

Deflection scanning unit 226 can deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 can comprise electrons with a distribution of energies including secondary electrons (energies ≤50 eV) and backscattered electrons (energies between 50 eV and landing energies of beamlets 214, 216, and 218). Secondary optical system 242 can focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Next, an example of a single-beam electron beam tool will be discussed. As shown in FIG. 4, an electron beam tool 104A includes a wafer holder 136 supported by motorized stage 134 that can hold wafer 230 to be inspected. Electron beam tool 104A includes an electron emitter, which may comprise a cathode 103, an anode 120, and a gun aperture 122. Electron beam tool 104A further includes a beam limit aperture 125, a condenser lens 126, a column aperture 135, an objective lens assembly 132, and an electron detector 144. Objective lens assembly 132, in some embodiments, is a modified SORIL lens, which includes a pole piece 132a, a control electrode 132b, a deflector 132c, and an exciting coil 132d. In a general imaging process, the electron beam 161 emanating from the tip of the cathode 103 is accelerated by anode 120 voltage, passes through gun aperture 122, beam limit aperture 125, condenser lens 126, and is focused into a probe spot by the modified SORIL lens and then impinges onto the surface of wafer 230. Backscattered or secondary electrons emanated from the wafer surface are collected by detector 144 to form an image of the interest area.

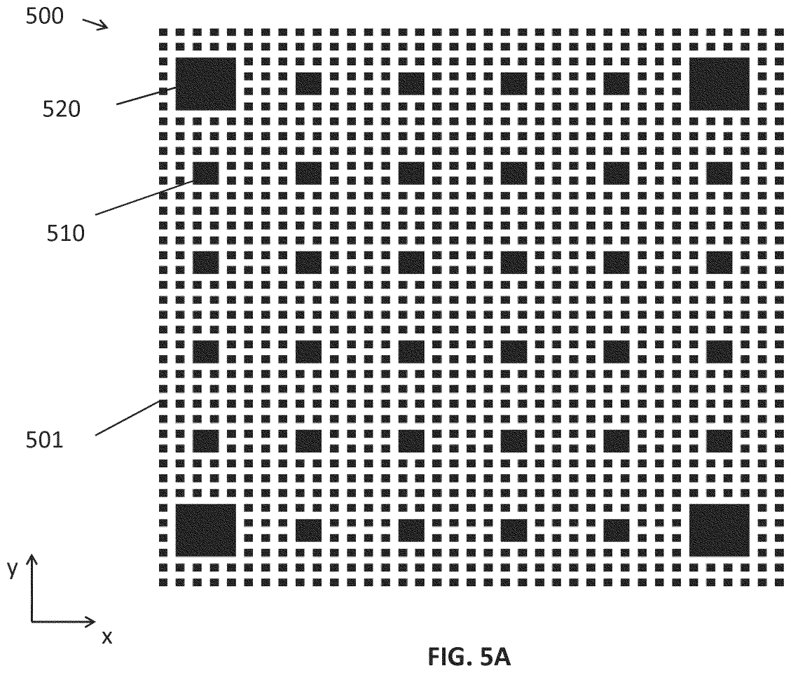

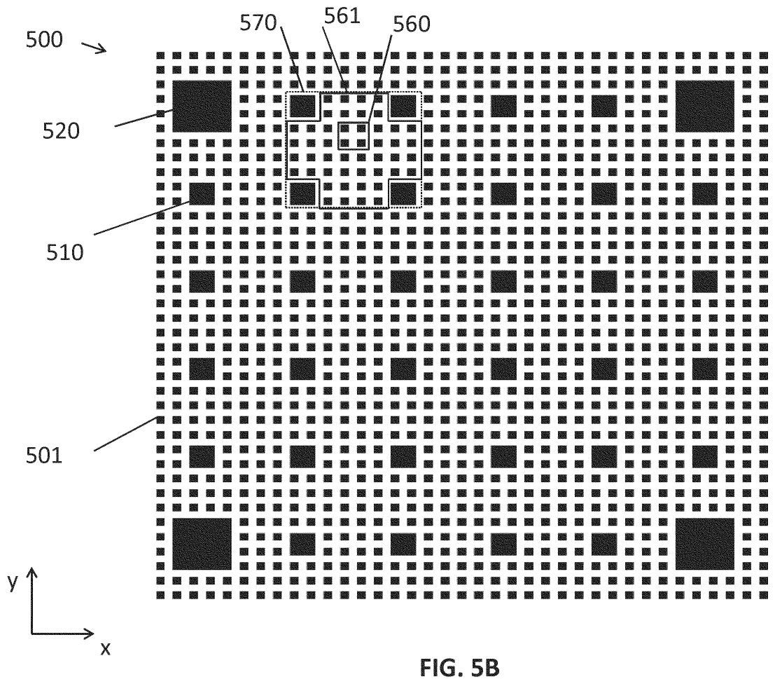

FIG. 5A illustrates a pattern 500 that may be used as a design of a reference standard formed in a wafer. Pattern 500 may be a design drawn using a GDS system, an open artwork system interchange standard (OASIS) system, a graphical processing system, and the like. Pattern 500 may be used as a design for a mask for etching a pattern on a wafer surface.

A reference standard can be formed on a wafer by various other methods, for example micro-machining, lithography, chemical deposition, etc.

Pattern 500 comprises a first dot 501. First dot 501 may be a rectangle. First dot 501 may be the smallest feature compatible with a manufacturing method. For example, in an etching application, the smallest feature may be defined by the etching process limit. First dot 501 may have a size greater than the feature size limit of an intended manufacturing method. First dot 501 can be used as the nominal dimension for pattern 500. In other words, first dot 501 may define a dimension of one unit.

Pattern 500 also comprises second dot 510. Second dot 510 may be a rectangle and may be geometrically similar to first dot 501. Second dot 510 is larger than first dot 501. Second dot 510 may have side length that is three times that of first dot 501. Thus, second dot 510 may have a size corresponding to nine units. That is, second dot 510 can be made up of nine first dots.

Pattern 500 may comprise third dot 520. Third dot 520 may be a rectangle and may be geometrically similar to first dot 501 and to second dot 510. Third dot 520 may have a side length that is seven times that of first dot 501. Thus, third dot 520 may have a size corresponding to 49 units.

In pattern 500, a plurality of first dots are provided such that first dot 501 is one of a plurality of the first dots. Each of the plurality of first dots may be identical. The plurality of first dots are aligned in an axis direction of the coordinate system of pattern 500. As shown in FIG. 5A, pattern 500 may be provided with x- and y-axes corresponding to horizontal and vertical directions, respectively. The plurality of first dots are aligned in the x-axis direction and in the y-axis direction such that side edges of the plurality of first dots lie along a line. The plurality of first dots are provided in a repeating pattern such that the first dots are spaced uniformly. The plurality of first dots may be provided at regularly spaced intervals. The length of the regularly spaced intervals may be the same as that of side edges of the first dots. That is, the dots may be spaced apart by one unit.

Pluralities of the larger dots of pattern 500 may also be provided. For example, a plurality of second dots are provided such that second dot 510 is one of a plurality of the second dots. Each of the plurality of second dots may be identical. The plurality of second dots are aligned in an axis direction of the coordinate system of pattern 500. Side edges of the second dots may be spaced from other dots by the same interval as the regular interval spacing of the first dots, or by some other distance.

Further, a plurality of third dots are provided such that third dot 520 is one of a plurality of the third dots. Each of the plurality of third dots may be identical. The plurality of third dots are aligned in an axis direction of the coordinate system of pattern 500. Side edges of the third dots may be spaced from other dots by the same interval as the regular interval spacing of the first dots, or by some other distance.

The larger dots of pattern 500 may be aligned with the plurality of first dots. The larger dots may be aligned in various ways. For example, as shown in FIG. 5A, the plurality of second dots are aligned such that side edges of the plurality of second dots lie along a line that is collinear with side edges of the plurality of first dots.

The larger dots may also be aligned such that their side edges are offset from the smaller dots. For example, as shown in FIG. 5A, the plurality of third dots are aligned such that side edges of the plurality of third dots lie along a line that is spaced apart from a line collinear with side edges of others of the dots. In FIG. 5A, the plurality of third dots are aligned with the centers of the plurality of second dots.

A pattern such as pattern 500 can extend for an arbitrary length in the x-axis and y-axis directions. Pattern 500 may be sized so as to be contained on a side of a die on a wafer. For example, pattern 500 can be located adjacent to a functional pattern on a wafer.

While FIG. 5A shows three different sizes of dots, further different sized dots can be provided. For example, pattern 500 may continue to scale to an arbitrary degree. Different sized dots and/or other features may be provided according to an exponential progression on the basis of the one unit.

Furthermore, in addition to a rectangle, the dots can be designed to be other shapes, for example, a square.

FIG. 5B shows pattern 500 and indicated regions of groups of dots. For example, a region 560 comprises a plurality of the first dots arranged in a repeating pattern. A region 570 comprises a plurality of the second dots arranged in a repeating pattern. Furthermore, a region 561 comprises a plurality of first dots arranged between a group of the second dots. Regions 560 and 570 overlap. For example, region 560 is entirely contained in region 570.

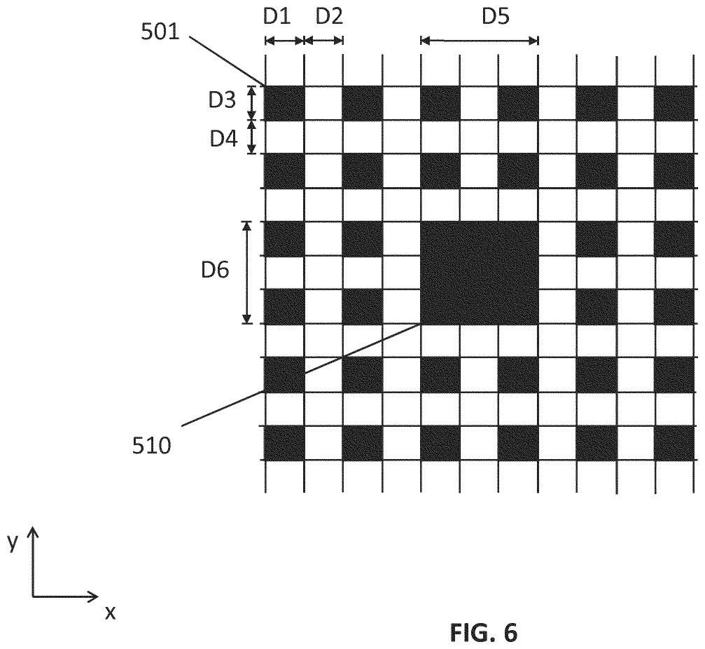

FIG. 6 illustrates a detailed view of pattern 500. As shown in FIG. 6, first dot 501 has dimensions of D1 by D3. D1 and D3 may be the same or different from each other. All of the first dots may have dimensions of D1 by D3. The first dots are spaced apart from one another by a regular interval, for example, D2 and D4. D2 and D4 may be equal to D1 and D3, respectively. In some embodiments, D2 and D4 may be smaller than D1 and D3, respectively. In some embodiments, D2 and D4 may be larger than D1 and D3, respectively.

Second dot 510 has dimensions of D5 by D6. D5 may be equal to three times D1, or may be some other value. D5 and D6 may be the same or different from each other. Second dot 510 is spaced apart from the first dots by an interval of D2, D4.

Because the first dots have side edges that are aligned, edge detection may be facilitated. For example, although the individual dots are separated from one another, because their edges lie along a common line, it may be easier for an image processing algorithm to detect an edge from a captured image. The edge may be a common edge of the first dots. Furthermore, because the first dots and second dots may have side edges that are aligned, as shown in FIG. 5A and FIG. 6, edge detection may be further facilitated.

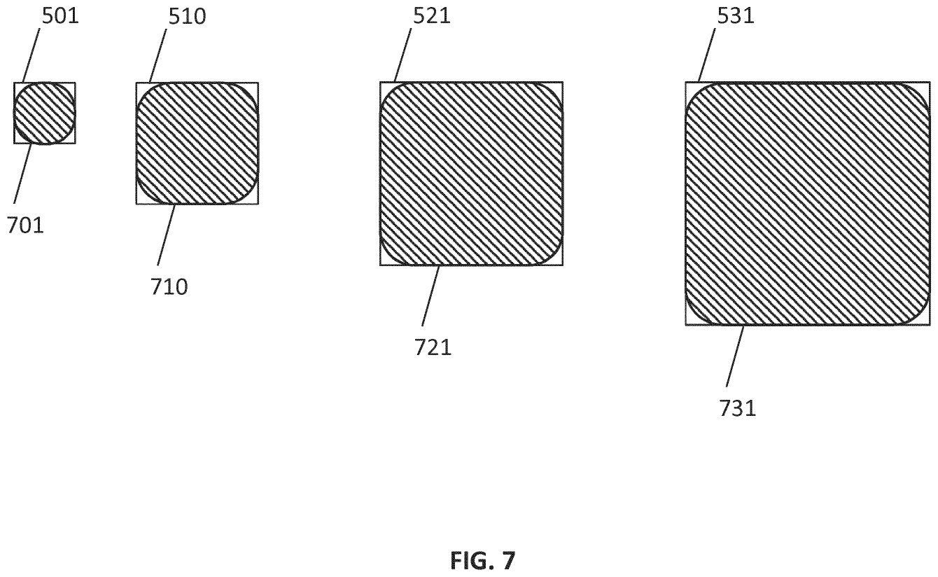

FIG. 7 illustrates an effect of manufacturing of different sized dots. For example, when a design is transferred to a wafer, the resulting objects formed on the wafer may not be identical to the design. Patterns may be transferred to a wafer by methods such as lithography, chemical deposition, etching, etc. Some manufacturing methods may have resolution limits, and may exhibit greater distortion and/or irregularity at varying scales. In an exemplary etching method, objects designed to have rectangular corners may actually result in objects having rounded corners. This effect may be exaggerated for smaller patterns.

In FIG. 7, for example, first dot 501 may correspond to a first object 701 after being formed on a wafer. First object 701 may be an etched pillar feature on the wafer surface. Second dot 510 may correspond to a second object 710 formed on the wafer. A third dot 521 that may have dimensions larger than that of second dot 510 may correspond to a third object 721 formed on the wafer. A fourth dot 531 that may have dimensions larger than that of third dot 521 may correspond to a fourth object 731 formed on the wafer.

Due to the effects of etching, objects may exhibit rounded corners. This effect is most extreme in smaller features. For example, first object 701, second object 710, and third object 721 have rounded corners such that these objects may appear rounded rather than square. Based on properties and parameters of the manufacturing method, objects may approach a substantially rounded shape. For example, object 701 may have a substantially circular shape. In some embodiments, object 701 may be a perfect circle. Dot 501 may be sized according to a minimum feature size based on process limits of a manufacturing method.

Fourth object 731 may exhibit some effects of rounded corners. However, relative to its total size, the rounded corners may be insignificant. For example, fourth object 731 may comprise substantial linear side edges over 80% of its total length. Thus, an image processing algorithm may detect a step edge feature of fourth object 731 individually.

Although some objects may exhibit rounded corners, some exemplary embodiments may accomplish accurate tuning and/or calibration, as will be described in detail later. Increasing the resolution of manufacturing processes, such as etching, may add to cost and complexity. Comparatively, it is easier to manufacture small round objects. Therefore, some exemplary embodiments may provide a pattern suitable for tuning and/or calibration while avoiding the need for expensive high-resolution etching techniques.

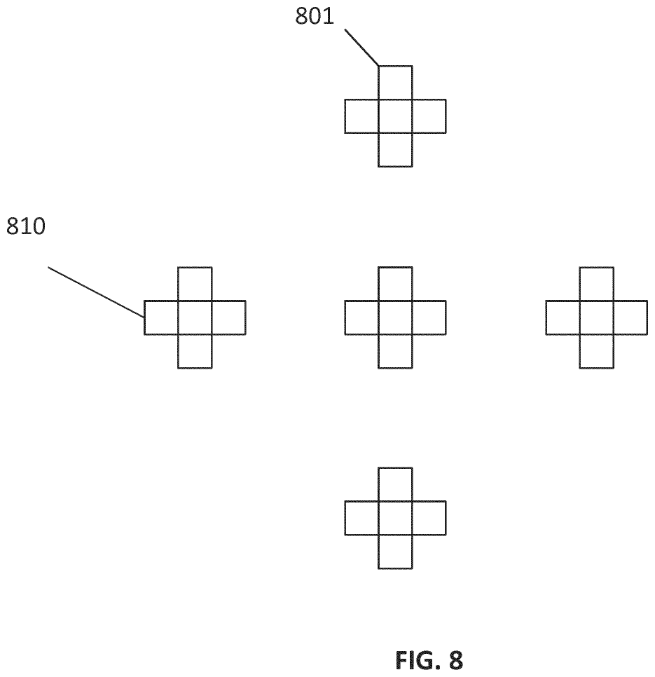

In addition to rectangular shapes, a pattern may comprise other shapes, such as crosses. For example, as shown in FIG. 8, a pattern may be provided with a plurality of crosses. In FIG. 8, a cross 810 is provided. Cross 810 may be one of a plurality of crosses. Each of the crosses may have similar dimensions. Alternatively, some crosses may be larger than others. Cross 810 may be made up of a plurality of unit blocks 801. The plurality of crosses may be aligned.

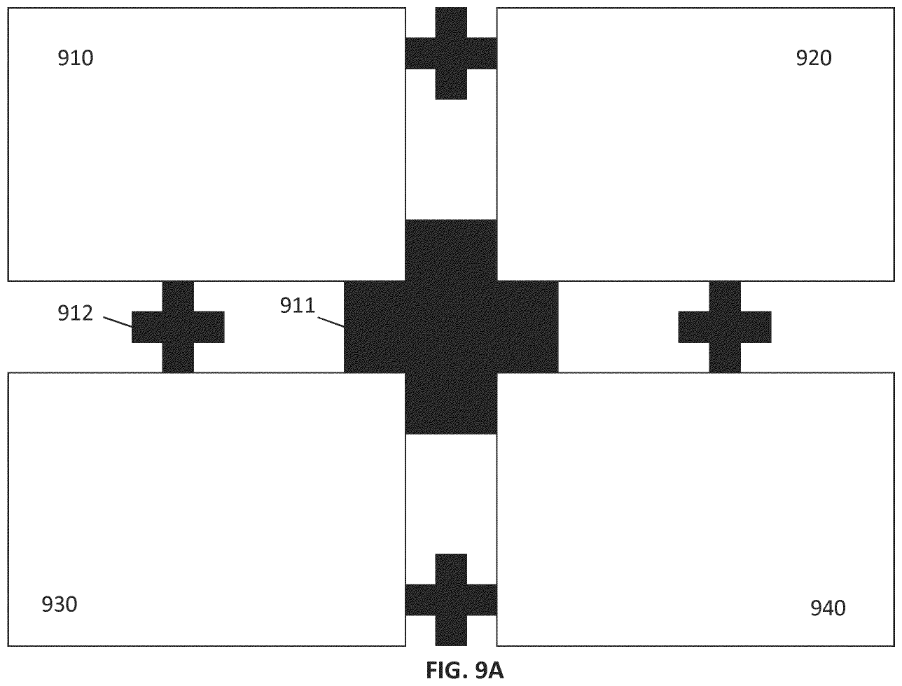

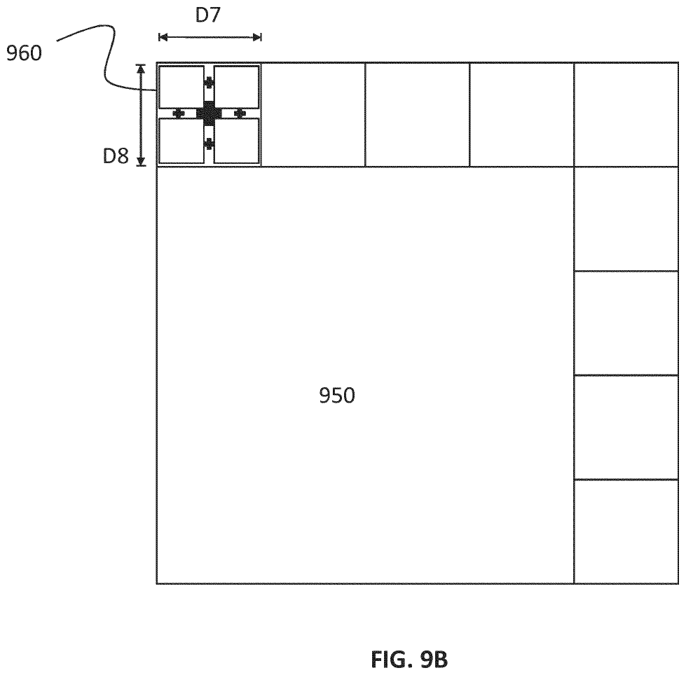

Crosses may be conveniently placed at intersections of patterning regions on a wafer. For example, as shown in FIG. 9A, crosses may be provided at areas between separate pattern regions, such as region 910, region 920, region 930, and region 940. Each of regions 910, 920, 930, 940 may be a region containing a unique pattern. The regions may comprise functional patterns, calibration patterns, and other patterns, etc. A large cross 911 may be placed at the center between all four regions. A small cross 912 may be placed at in area between region 910 and region 930. Cross 912 may be one of a plurality of small crosses that have similar dimensions.

Crosses may be useful for mirror flatness calibration. For example, large crosses at a relatively large period are useful for low-high SEM offset and small crosses at a relatively short period are useful for mirror calibration.

Dies on a wafer may be constructed with reference standard patterns contained therein. For example, as shown in FIG. 9B, a pattern 960, such as that shown in FIG. 9A, may be located on a side of a main area 950. Pattern 960 may have dimensions of D7 by D8, and may be replicated at a plurality of locations along the side of main area 950. In some embodiments, D7 and D8 may be 2 mm.

A reference specimen can be manufactured according to a particular application. For example, a reference specimen can be provided with a variety of patterns that are useful for an application. Some exemplary embodiments are provided in Table 1, below.

TABLE 1

| | Pixel | | | | |
|---|---|---|---|---|---|
| | size | Object size | Object | | |
| Application | (μm) | (μm) | shape | Period | Description |
| Ep5, HR | 0.0005-0.005 | 0.050 | Square | 0.100 | Dense grid having high |
| review | | | | | resolution, accuracy, and |
| | | | | | precision in SEM tuning and |
| | | | | | calibration |
| 500 / physical | 0.005-0.015 | 0.150 | Square | 0.600 | Connect 4 closest dots to |
| defects | | | | | make larger square dot |
| 500 / physical | 0.015-0.035 | 0.350 | Square | 3.000 | Sparse grid with larger |
| defects | | | | | squares for coarse focus, |
| | | | | | stigmator, aperture alignment. |
| 400 / voltage | 0.035-0.075 | 0.550 | Square | 15.000 | Sparse grid with large squares |
| contrast | | | | | to create a locally unique |
| defects | | | | | pattern for large |
| | | | | | deflection/FOV |
| Mirror | 0.110-0.700 | 5 × 0.500 | Small | 1000.000 | Row and column of crosses, |
| flatness | | and 0.500 × | crosses 0.5 | | spaced by 1 mm, to calibrate |
| | | 5.000 | mm away | | mirror flatness |
| | | | from center | | |
| | | | of 4 regions | | |
| High | 0.625-1.500 | 40 × 4 and | Large cross | 2000.000 | Create 4 (0.95 mm × 0.95 |
| magnification | | 4 × 40 | at center of | | mm) regions: square dot = |
| image | | | 4 regions | | 0.025, round dot = 0.025, |
| | | | | | larger square dot = 0.50, |
| | | | | | round dot = 0.050 |
| Low | 2.5-15.0 | 1000 × 40 | Blank | 2000.000 | Connect 4 regions into large |
| magnification | | and 40 × | space | | strips of 20 mm × 2 mm to |
| image | | 1000 | surrounding | | check throughput with |
| | | | 1 small and | | minimal blank space < 5 μm |
| | | | 4 large | | in between the 4 regions |
| | | | crosses | | |

Table 1 is based on an exemplary nominal dot size of 0.050 μm. However, it will be appreciated that a nominal size can be adjusted. According to the nominal size, corresponding values in the table may be adjusted accordingly. For example, when a nominal size is 0.080 μm, in an ep5 application, an object size becomes 0.080 μm with a period of 0.160 μm. Also, in a 500/physical defects application, object size becomes 0.240 with period of 0.960. Objects for mirror flatness, high magnification image, and low magnification image applications may not change based on the nominal dot size, for example.

Image acquisition may comprise generating an inspection beam by an electron beam tool and scanning the beam in a pattern (for example, a raster pattern) over the sample to be inspected. An image acquirer may be configured to acquire an image of a first imaging area by having the inspection beam scan over the surface of the sample in a first region and detecting a signal output from a detector. Range of beam scanning may be limited by the field of view (FOV) of the electron beam tool, and thus, the first imaging area may be coincident with the FOV. To image another area, the sample is moved by a sample stage and the beam is scanned over a new area. In a leap-and-scan mode, imaging may be conducted at a particular region within the FOV, and when complete, the stage is moved and the process repeats.

In a continuous-scan mode, imaging may be conducted continuously while a wafer is carried by movable stage along x- and y-directions. For example, the stage may be moved in a relatively slow and continuous (or nearly continuous) linear motion under a charged particle beam column. Meanwhile, one or more charged particle beams generated by a charged particle source may be scanned linearly back-and-forth along scan lines in a pattern, such as a raster pattern. Thus, the one or more charged particle beams are moved so as to cover the moving wafer in discrete strip-shaped segments.

An exemplary method for tuning and/or calibrating will be discussed.

A charged particle tool may be used for generating a primary charged particle beam and/or a plurality of beamlets. The charged particle tool may be used to scan the beam or beamlets across the surface of a sample. The sample may comprise a reference standard such as those discussed above. Secondary charged particles may be emanated from the sample and detected by a detector. An image acquirer coupled to the detector for receiving a detection signal may form a scanned raw image. The image acquirer may comprise one or more processors.

The raw image may be analyzed in a variety of ways. For example, image processing may be performed. In some embodiments, an image processing algorithm may be used to analyze the raw image. An image processing algorithm may comprise the use of a transfer function, such as Fast Fourier Transform (FFT) or wavelet transform (WT), or a kernel, for example. A wavelet transform may be a continuous wavelet transform or a discrete wavelet transform. WT functions may be useful when modeling images. Image processing may comprise a plurality of steps wherein the image processing algorithm is used with various parameters. For example, in a first step, an image processing algorithm may be used with a first parameter. The first step may correspond to a coarse search. In a second step, an image processing algorithm may be used with a second parameter. The second step may correspond to a fine search.

The one or more processors may be configured to acquire an image at a predetermined sampling rate and to perform image processing using an image processing algorithm on the raw image.

In some embodiments, a kernel may be used with an imaging processing algorithm. A kernel, such as a convolution matrix, may be useful for edge detection in image processing. Convolution may comprise a process of adding each element of an image to its local neighbors, weighted by the kernel. Parameters of a kernel may comprise components of a convolution matrix. Parameters may also comprise a size of an edge detector kernel.

An exemplary image processing method may comprise searching for features from coarse to fine scales. A first search may be performed that results in a first global profile of sharpness. For example, when the image processing algorithm comprises a transfer function, searching may comprise searching for low frequency components first, then moving on to high frequency components. Parameters of a transfer function may comprise frequency levels.

When the image processing algorithm comprises a kernel, searching may comprise finding a slope with a large kernel size first, then moving on to smaller kernel sizes. For example, an initial kernel size may be [−1, 0, 0, 0, 0, 0, 0, 0, +1] (having a length=8 pixel). Such a kernel may be useful to detect edges and large shapes with large spacing. A global profile of sharpness or focus can be found that has a unique peak with very wide sloping regions on both sides for convergence.

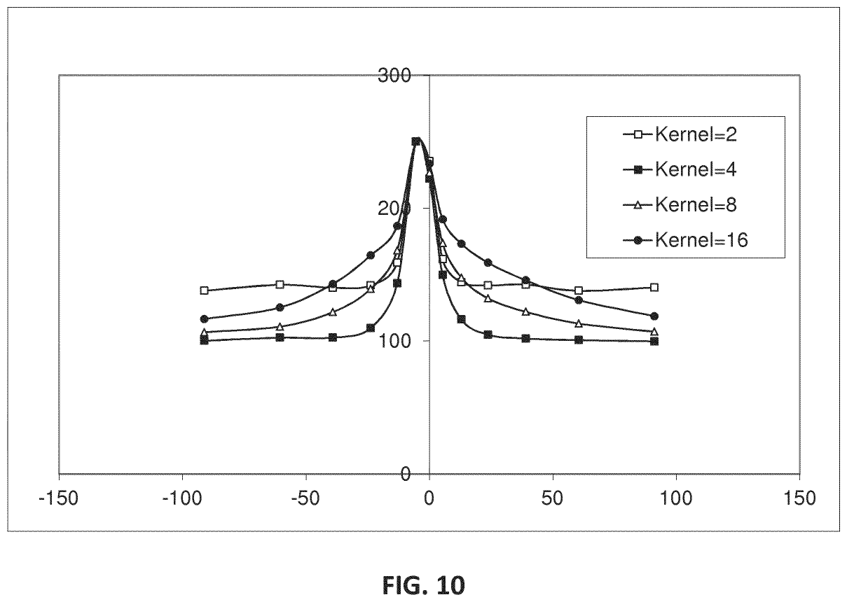

FIG. 10 illustrates an example of results of image processing on a raw image. In the graph of FIG. 10, the horizontal axis represents focus and the vertical axis represents sharpness. Units of sharpness may be, for example GL/pixel, and units of focus may be, for example mA. The graph of FIG. 10 contains a plurality of data series that may correspond to different coarseness levels. In some embodiments, different coarseness levels may correspond to different levels of wavelet transform, or different sizes of edge detector kernels. For example, a first series may represent a fine level WT, or an edge detector kernel size of 2. In the first series, left and right tails are relatively flat and have weak maxima.

A fourth series may represent a coarse level WT, or edge detector kernel size of 16, for example. In the fourth series, left and right tails have well-defined slopes that lead to the peak. Thus, convergence is possible from further away from the peak.

While a large kernel (or coarse WT) is useful for initial convergence, a large kernel may yield a relatively flat peak. Thus, a large kernel has poor stopping accuracy. A smaller kernel size may then be used, for example [−1, +1], to detect instantaneous slope at the many edges of small shapes. Accordingly, a precise stopping point can be obtained.

A plurality of different parameters may be used with image processing algorithms to obtain various data series. Each of the data series may exhibit different characteristics according to the parameters. For example, the curvatures of the peaks of coarse versus fine data series, such as the first through fourth series, may be different by a factor of 4× to 10×. Different data series may have different useful applications. For example, when optimizing for max sharpness versus focus when analyzing an image consisting of only small dots, a data series may be yielded having a peak with very large curvature. Such a peak has a narrow convergence region, and has relatively flat tails on both sides. Flat tails are sensitive to SEM noise, so the tails themselves may also comprise many small peaks. Accordingly, tuning may become very difficult based only on a single, particular data series.

In some embodiments, image processing comprises a plurality of steps wherein different image processing is performed on an imaging region. The plurality of steps may comprise using a plurality of different image processing algorithms. The plurality of steps may comprise using the same image processing algorithm but with different parameters.

The imaging region may comprise an area on a wafer comprising a reference standard. The reference standard may comprise a planar substrate having a plurality of regions.

For example, a first region may comprise a plurality of first objects at a first scale. The first objects may have a first size and may be spaced apart from one another at a first period. A second region may comprise a plurality of second objects at a second scale. The second objects may have a second size and may be spaced apart from one another at a second period. The first region and the second region may have characteristics different from each other. For example, the first scale may be smaller than the second scale. The first size may be smaller than the second size. The first period may be smaller than the second period. The reference standard may be configured so that the first region and the second region overlap. In some embodiments, the second region may comprise the plurality of second objects, wherein the plurality of first objects are arranged between the plurality of second objects.

In an exemplary tuning and calibration method, the imaged area comprises a reference standard comprising a plurality of different sized dots as discussed above. Based on a measure of sharpness, imaging conditions can be adjusted. For example, beam defection or stage position and/or angle can be adjusted in order to obtain a fully focused image having a desired pixel size and angle.

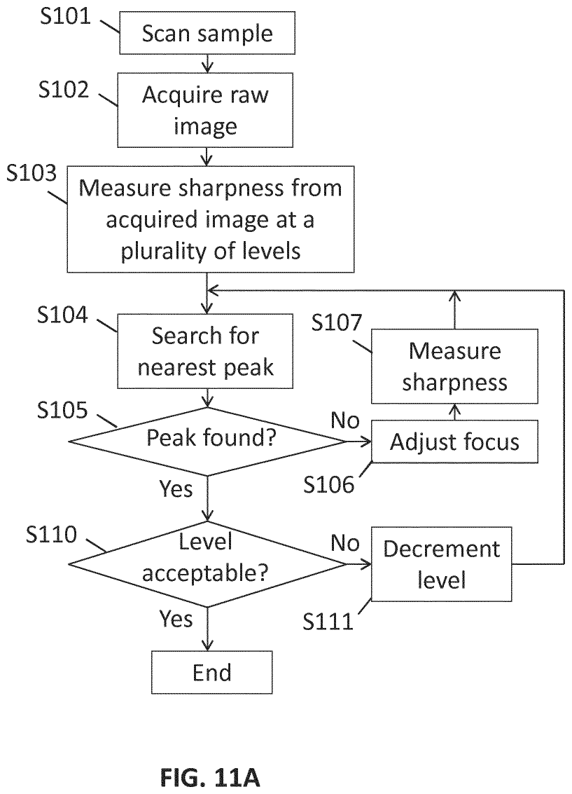

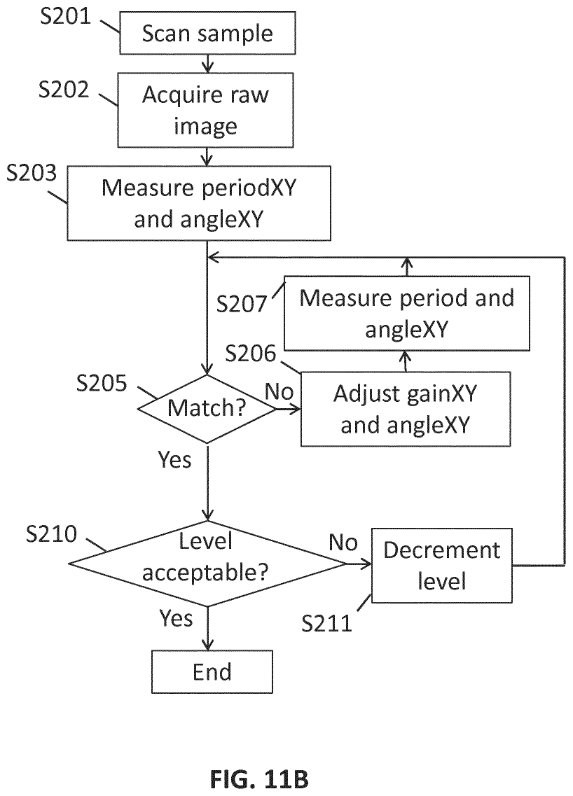

FIG. 11A and FIG. 11B illustrate a flow charts of exemplary image processing methods. These methods can be performed by one or more processors coupled with a charged particle beam apparatus. For example, these methods can be performed by controller 109.

FIG. 11A may represent an exemplary tuning method. In a step S101, a charged particle beam apparatus scans a sample comprising a reference standard. In a step S102, a scanned raw image of the imaging area may be obtained. When the charged particle beam apparatus is a multi-beam apparatus, a plurality of imaging beams may be generated. Accordingly, a plurality of images corresponding to each of the beams or beamlets may be generated. For example, for a 9-beamlet apparatus, 9 images may be generated and acquired for 9 threads. The plurality of beams may image the same imaging area. The charged particle beam apparatus may be configured to acquire an imaging area on the reference standard including at least four larger dots in a rectangular arrangement. In a step S103, for each thread, measurement is performed to measure sharpness from an acquired image at a plurality of coarseness levels. The coarseness levels may correspond to image processing that is performed using different image processing algorithms or using different parameters with the same image processing algorithm.

Searching for peak sharpness may be performed at the plurality of coarseness levels. Searching may be performed in a sequence from coarse to fine. In a step S104, searching may be performed first at a predetermined level of the plurality of coarseness levels. For example, the first level may be the coarsest of the plurality of levels. When the coarseness levels are indexed from high (coarse) to low (fine), the coarsest level may be that having the highest numerical value. Next, in a determination step S105, it is determined whether a peak has been found and the current level of focus is at the peak.

If a determination is affirmative, the method proceeds to a determination step S110. In step S110, it is determined whether the current coarseness level is acceptable. Determination of whether the coarseness level is acceptable may comprise comparing the current coarseness level with a predetermined threshold. A result of determination in step S110 may be affirmative when the current coarseness level is less than or equal to the predetermined threshold. For example, the predetermined threshold may be the finest level among the plurality of coarseness levels. In some embodiments, a different value for the predetermined threshold may be, for example, a level of the plurality of coarseness levels that is determined to be suitable for an application.

In the above manner, for example, the method may iterate a plurality of times. In some embodiments, a stopping criteria may be provided. The stopping criteria may be used instead of or in addition to comparing the current coarseness level to the predetermined threshold. The stopping criteria may be configured so that iteration stops upon reaching a threshold level that may correspond to imaging resolution. The threshold level may be determined in advance. For example, the threshold level may be a pixel level.

If the determination in step S110 is affirmative, it may be judged that the image is in-focus and the method ends.

If the determination in step S110 is negative, it may be judged that confirmation is required, and the method advances to a step S111. In step S111, the current coarseness level is decremented. For example, the current coarseness level may be decreased by one. Next, the method returns to step S104 and searches for the nearest peaks. If, at the new coarseness level, a peak is found and the current level of focus is at the peak (Yes in S105), the method may proceed to step S110.

However, if it is determined that the current level of focus is not at the peak, tuning may be required. For example, if a determination in step S105 is negative, that is, the current level of focus is not at the maximum of the peak, tuning processing may be performed at a step S106.

Tuning processing may comprise further determinations. For example, if the current level of focus is relatively close to a peak maximum within a predetermined range, interpolation may be performed. A parabola representing sharpness may be generated. The parabola may be interpolated to find a more accurate focus. Alternatively, if the current level of focus is on a sloped area of the graph of sharpness, focus control may be adjusted in the direction of the slope that approaches the peak.

Adjustments of focus, such as step size, may correspond with the current coarseness level. For example, the coarser the level, the larger the adjustment, and likewise, the finer the level, the finer the adjustment.

After adjusting the focus in step S106, sharpness may be measured again in a step S107. The sharpness measurement performed in step S107 may comprise measurements at the current coarseness level and at levels of the plurality of coarseness levels finer than the current coarseness level. That is, a measurement at a level coarser than the current coarseness level can be omitted. Next, the method returns to step S104 and searches for the nearest peaks.

In the above manner, an iterative process can be employed for tuning a charged particle beam apparatus.

FIG. 11B may represent an exemplary calibration method. In a step S201, a charged particle beam apparatus scans a sample comprising a reference standard. The reference standard may comprise dots and grids at a plurality of scales, for example, at four scales. In a step S202, a scanned raw image of the imaging area may be obtained. When the charged particle beam apparatus is a multi-beam apparatus, a plurality of imaging beamlets may be generated. Accordingly, a plurality of images corresponding to each of the beamlets may be generated. For example, for a 9-beamlet apparatus, 9 images may be generated and acquired for 9 threads. The plurality of beamlets may image the same imaging area. The charged particle beam apparatus may be configured to acquire an imaging area on the reference standard including at least four largest dots in a rectangular arrangement in a pattern comprising four different sizes of dots.

In a step S203, for each thread, a measurement is performed to measure calibration parameters. For example, the measurement may comprise measuring periods in x- and y-axis directions (periodXY) and/or angles from x- and y-axis directions (angleXY) from an acquired image at one or more coarseness levels. Thus, four parameters may be measured at one or more coarseness levels. The four parameters may be analyzed with a 2×2 transform. The coarseness levels may correspond to image processing that is performed using different image processing algorithms or using different parameters with the same image processing algorithm.

Also in step S203, measuring may comprise finding a projection profile along x- and y-axes. Furthermore, measuring may comprise smoothing the projection profiles and correlating profiles by integer multiples of measured periods to find accurate period and angles at a particular coarseness level.

Next, in a determination step S205, it is determined whether the measured period is equal to a known period and/or whether the measured angle is aligned with or perpendicular to an axis direction. The known period may be based on known dimensions of the reference standard, for example, GDS designs.

If a determination in step S205 is negative, it may be judged that calibration is required, and the method advances to a step S206. In step S206, calibration may be performed. For example, the gain and/or the angle may be adjusted. Furthermore, a plurality of corrections according to the plurality of coarseness levels can be made. After making adjustments in step S206, parameters may be measured again in a step S207. The measurement performed in step S207 may comprise measurements at the current coarseness level and at levels of the plurality of coarseness levels finer than the current coarseness level. That is, a measurement at a level coarser than the current coarseness level can be omitted. Next, the method returns to step S205 and determines whether the measured period is equal to a known period and/or whether the measured angle is aligned with or perpendicular to an axis direction.

If a determination in step S205 is affirmative, that is, the measured period is equal to the known period of a particular level and/or measured angle is perpendicular to an axis direction, it may be judged that the imaging system is calibrated at the current level. The method then proceeds to a determination step S210. In step S210, it is determined whether the current coarseness level is acceptable. Determination of whether the coarseness level is acceptable may comprise comparing the current coarseness level with a predetermined threshold. A result of determination in step S210 may be affirmative when the current coarseness level is less than or equal to the predetermined threshold. For example, the predetermined threshold may be the finest level among the one or more coarseness levels. In some embodiments, a different value for the predetermined threshold may be, for example, a level of the one or more coarseness levels that is determined to be suitable for an application.

In the above manner, for example, the method may iterate a plurality of times. In some embodiments, a stopping criteria may be provided. The stopping criteria may be used instead of or in addition to comparing the current coarseness level to the predetermined threshold. The stopping criteria may be configured so that iteration stops upon reaching a threshold level that may correspond to imaging resolution. The threshold level may be determined in advance. For example, the threshold level may be a pixel level.

If the determination in step S210 is negative, it may be judged that further calibration is required, and the method advances to a step S211. In step S211, the method may perform a refinement. For example, the current coarseness level may be decremented. The current coarseness level may be decreased by one. Next, the method returns to step S205. If, at the new coarseness level, it is determined that the measured period is equal to a known period and/or the measured angle is aligned with or perpendicular to an axis direction (Yes in S205), the method may proceed to step S210.

However, if it is determined that the measured period deviates from the known period and/or the measured angle is not aligned with or perpendicular to axis directions, calibration may be required. For example, if a determination in step S205 is negative, calibration processing may be performed at step S206.

In the above manner, an iterative process can be employed for calibrating a charged particle beam apparatus.

In a calibration process, the reference standard may be used as a ruler in x- and y-axis directions having a plurality of gratings. For example, larger gratings comprise larger dots. Larger gratings allow a global pattern matching. Larger gratings may be useful to find a rough pixel size that may be accurate to a first digit (that is, +/−10%). Smoothing may be employed to smooth x- and y-axis direction projection profiles to observe only the ruler with larger gratings. To obtain a pixel size that is accurate to a next digit, for example, second and third digits (that is, +/−1% and +/−0.1%, respectively), less smoothing can be employed so as to match to fine gratings that are very dense. Accordingly, a small sigma error can be achieved.

A calibration process may comprise performing matching in a serial progression from coarse to fine coarseness levels. For example, attempting to match the smallest size dots initially without smoothing may result in a correlation function that is a periodic curve with many peaks spaced by a very small period. In such a scenario, location errors are more likely, especially in the presence of large SEM noise, local shape errors, and etching roughness, etc. Smoothing can be employed to smooth out the small dots, leaving only the larger dots in the x- and y-axis direction projection profiles. Therefore, a rough but correct period can be obtained by employing smoothing.

Tuning and/or calibrating a charged particle beam apparatus may employ image processing including pyramid representation. For example, image processing may comprise computing an image pyramid. A charged particle beam apparatus may be configured to image a reference standard that comprises dots at two or more scales. An image pyramid may be a collection of images derived from a single imaging area that are successively down-sampled until a desired stopping point is reached. In some embodiments, a Gaussian pyramid can be used. When a pyramid is used, an image is smoothed and down-sampled to obtain the next coarseness level. Pattern matching may start at a coarse level to find a correct match, but with a rough location. Then, tuning and/or calibration can be refined. For example, next digit precision can be obtained by progressing to a finer level. Refinement can proceed until a desired pixel level is reached. In this manner, matching can be performed at multiple scales.

For example, employing a pyramid, a calibration process may start with matching large dots, using smaller images at the top of the pyramid. Parameters may be measured, for example periodXY and angleXY. Then, the parameters can be corrected in a deflection scan to calibrate the small and coarse image to be square. PeriodXY and angleXY can be corrected in a 2×2 transform. Such a coarse match is unique and simple, and thus may have a high success rate. Furthermore, by beginning with larger scales, larger distortions may be corrected early.

Next, measurements may be refined to find parameter corrections using images at the next lower coarseness level. Such images may contain more details from smaller dots in the imaging area. Refinement may be local, and thus may have a high success rate. Iteration may continue until reaching pixel level, for example.

When a multi-beam apparatus is used, scanning can be done by deflecting the plurality of generated beams (or beamlets) together. Thus, when scanning rows from top to bottom, a plurality of images can be generated corresponding to the plurality of beams. Each image can be transmitted to a computer that may measure sharpness. The computer may also perform further processing including finding two periods and two angles for a 2×2 linear transform (scaling and rotation), plus two offsets (translation).

In some embodiments, since the plurality of beams of a multi-beam apparatus may image the same region, there may be a plurality of threads corresponding to a number of parallel searches equal to the number of the plurality of beams. Movement from one sample site having objects of a particular size to another sample site having objects of another size to refine and obtain better precision can be omitted. Furthermore, the plurality of threads need not be coordinated. Accordingly, some of the threads may complete their processing earlier than others. Furthermore, the communication exchange between the plurality of threads may be omitted. The more points sampled, the more precise the location. Thus, throughput and precision can both be enhanced. Additionally, because peaks may be unique, and no bias is introduced in location, precision and repeatability imply enhanced accuracy.

Objects of a reference standard may exhibit some fluctuation in dimensions. For example, due to manufacturing variability, objects may have sizes within a range of +/−10% from a nominal value. In some embodiments, objects may have sizes +/−5% from a nominal value. In some embodiments, objects may have sizes +/−2% from a nominal value. While any one single dot may not be nm-accurate, an array can be provided where global dimensions over a distance of, for example, 100 periods or larger, are consistent. Furthermore, because a manufacturing method can be used that minimizes scaling error, for example, etching, relative error may be less than 0.5 per image size. Some embodiments may provide an array with dots small enough to be suitable for demanding image-to-GDS comparisons.

Furthermore, in an exemplary reference standard, borders of different sized shapes may be aligned to the smallest grid geometry. Thus, objects may be based on a uniform base shape and a uniform base geometry.

Patterns of a reference standard may comprise a plurality of repeated objects arranged across a common area. The objects may be of different sizes. Regions of the different sized replicated objects may overlap in part or completely. The reference standard may comprise a planar surface with the objects projected from the planar surface. For example, the objects may be formed by deposition. The objects may also be formed so that recessions are formed between adjacent objects, and the objects share a common top surface with their surroundings. That is, the objects and the wafer may have a common top planar surface. For example, the objects may be formed by etching.

An imaging system may comprise a computer. The computer may be coupled to a charged particle beam apparatus. The computer may comprise an image acquirer and may also comprise a tuner. The tuner may comprise one or more circuits configured to implement a tuning method. Furthermore, the tuner may comprise a computer readable medium programmed with instructions for carrying out a tuning method.

The tuner may comprise programming or circuitry for implementing one or more blocks of the flow chart of FIG. 11A.

A tuning method may be represented in a pseudo-code, for example, as follows:

(Repeat for all threads corresponding to a plurality of beams or beamlets)
a. Scan image (obtain plurality of images corresponding to the threads) at a first location.
b. For each thread:
   i. Measure sharpness at a plurality of coarseness levels from image (e.g., 4 levels).
   ii. Search for nearest peak (from coarse=3 to fine=0 level):
      1. If (foundPeak) then interpolate parabola to find more accurate focus.
      2. If (onSlope) then adjust focus control in the direction of current slope to approach peak. Smaller step size for finer level.
      3. If foundPeak && level==fine then Done.
      4. If foundPeak && level>fine then level-=1 (go down to next level).

The computer as discussed above may further comprise a calibrator. The tuner may comprise one or more circuits configured to implement a calibration method. Furthermore, the calibrator may comprise a computer readable medium programmed with instructions for carrying out a calibration method.

The calibrator may comprise programming or circuitry for implementing one or more blocks of the flow chart of FIG. 11B.

A calibration method may be represented in a pseudo-code, for example, as follows:

(Repeat for all threads corresponding to a plurality of beams or beamlets)
a. Scan image (obtain plurality of images corresponding to the threads) at a first location.
b. For each thread:
   i. Measure periodXY and angleXY from image: 4 parameters, by performing correlation from coarse to fine coarseness level.
      1. Find projection profile along x- and y-axes.
      2. For smoothing sigma from large to small:
         A. Smooth projection profile with sigma, and down-sample to obtain profile at pyramid level.
         B. correlate 2 profiles (distant by integer multiple of period) to find accurate period and angle at current coarseness level.
   ii. If (measured period==known period && angle is perpendicular)
      1. Then Done.
      2. Else adjust gainXY and angle XY, 4 corrections in deflection.

A tuning and calibration system may comprise a charged particle beam apparatus configured to analyze a reference specimen and a controller configured to implement a tuning method and/or a calibration method. Results of analyzing the reference specimen may be fed back into the tuning and calibration system to make adjustments to the charged particle beam apparatus. The charged particle beam apparatus can be focused to obtain an optimal and stable resolution compatible with the smallest spot size.

In a charged particle beam apparatus used as an imaging system, while an imaging area may be limited by a FOV, any one FOV may comprise a view of the reference specimen having multiple scales of dots that have their respective sizes and spacing. For example, small dots will be adjacent to one another by a small dot interval. Large dots will be adjacent other large dots by a larger interval.

In a multi-beam system, a multi-beam charged particle beam apparatus may be generally directed to a reference specimen and may be able to scan at a variety of locations to obtain an image having a plurality of scales. Furthermore, while each of a plurality of beams may be individually directed to different areas, because patterns of the reference specimen are replicated with regularity, each of the beams may image corresponding objects. Using the reference specimen for tuning and calibration may also minimize the number of images acquired for tuning and calibrating. While certain advantages are discussed in the context of a multi-beam system, it shall be understood that exemplary aspects of the present disclosure are applicable to single-beam systems as well. For example, even in a single-beam system, benefits can be obtained of eliminating stage moves from regions of large scale objects to regions of small scale objects. In any charged particle system, fewer images may be beneficial as high charged particle dosage has adverse effects on samples.

In some embodiments, the reference specimen may be sized and dimensioned as determined by optimization. For example, an optimization routine may comprise optimizing parameters including object size, spacing, and scaling. Optimization may be configured to yield a design so can achieve the best resolution while having a very large convergence region.

Tuning and calibration may be tailored to an application. For example, material defect inspection requires high resolution. Physical defect inspection requires mid-level resolution. Voltage contrast inspection requires low resolution (e.g., on the order of mm). Accordingly, tuning and calibration methods, and designs of a reference specimen, may be modified to accommodate for the intended application.

In some embodiments, a detector may communicate with a controller that controls a charged particle beam system. For example, the detector may transmit beam current output to the controller, and the controller may control various functions of the charged particle beam system in response. Exemplary forms of communication may be through a medium such as an electrical conductor, optical fiber cable, portable storage media, IR, Bluetooth, internet, wireless network, wireless radio, or a combination thereof. The controller may receive a signal from the detector and may construct an image. The controller may also perform various post-processing functions, image subdivision, image processing, generating contours, superimposing indicators on an acquired image, and the like. The controller may comprise a storage that is a storage medium such as a hard disk, random access memory (RAM), other types of computer readable memory, and the like. The storage may be used for saving scanned raw image data as original images, and post-processed images.

While a controller, storage, and one or more circuits are discussed above as separate units, a computer may carry out the processing of all such units.

A non-transitory computer readable medium may be provided that stores instructions for a processor of controller 109 to carry out tuning, calibration, image processing, and/or other functions. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments may further be described using the following clauses:

1. A planar substrate comprising:

a plurality of first objects having a first size and being located in a first region on the substrate spaced at a first period; and

a plurality of second objects having a second size and being located in a second region on the substrate spaced at a second period,

wherein
the first size is smaller than the second size, and
the first period is smaller than the second period.
   2. The substrate of clause 1, wherein the first region and the second region overlap.
   3. The substrate of any of clause 1 and clause 2, wherein the plurality of first objects comprise round shapes.
   4. The substrate of any of clauses 1 to 3, further comprising:

a plurality of third objects having a third size and being located in a third region on the substrate spaced at a third period,

wherein
the third size is larger than the second size,
the third region overlaps with the first region and the second region, and
the first size, the second size, and the third size follow an exponentially increasing progression.
   5. The substrate of clause 4 wherein the first period, the second period, and the third period follow an exponentially increasing progression.
   6. The substrate of any of clauses 1 to 5, wherein the plurality of first objects and the plurality of second objects are etched in the substrate.
   7. A method for adjusting a charged particle beam apparatus, comprising:

analyzing an image of a sample at a plurality of coarseness levels, the image comprising a plurality of first objects having a first feature size and a plurality of second objects having a second feature size;

determining whether a parameter of the image satisfies a predetermined criteria based on a first measured characteristic of the image at a first coarseness level of the plurality of coarseness levels;

determining whether the parameter of the image satisfies a predetermined criteria based on a second measured characteristic of the image at a second coarseness level of the plurality of coarseness levels; and

adjusting the parameter of the image based on a determination result based on the predetermined criteria.

8. The method of clause 7, wherein the image is analyzed at the plurality of coarseness levels using a plurality of image processing algorithms.
9. The method of clause 7, wherein the image is analyzed at the plurality of coarseness levels using an image processing algorithm with a plurality of parameters corresponding to the plurality of coarseness levels.
10. The method of clause 9, wherein the image processing algorithm comprises a transfer function.
11. The method of clause 10, wherein
the first coarseness level corresponds to a low frequency response of the transfer function, and
the second coarseness level corresponds to a high frequency response of the transfer function.
   12. The method of clause 9, wherein the image processing algorithm comprises a kernel.
   13. The method of any of clauses 7 to 12, wherein in response to determining that the parameter does not satisfy the predetermined criteria based on the first measured characteristic of the image at the first coarseness level, the image is analyzed at the second coarseness level.
   14. The method of any of clauses 7 to 13, further comprising acquiring the image of the sample based on a charged particle beam generated by the charged particle beam apparatus.
   15. The method of clause 14, wherein the charged particle beam comprises a plurality of beamlets generated by a multi-beam apparatus.
   16. The method of clauses 15, wherein the image comprises one or more images acquired for each of a plurality of threads corresponding to each of the plurality of charged particle beamlets.
   17. The method of any of clauses 7 to 16, wherein the parameter is focus of the charged particle beam apparatus.
   18. The method of any of clauses 7 to 17, further comprising tuning the charged particle beam apparatus.
   19. The method of any of clauses 7 to 17, further comprising calibrating the charged particle beam apparatus.
   20. A non-transitory computer readable medium comprising a set of instructions that are executable by one or more processors of an apparatus to cause the apparatus to perform a method comprising:
acquiring analysis of an image of a sample at a plurality of coarseness levels, the image comprising a plurality of first objects having a first feature size and a plurality of second objects having a second feature size;
determining whether a parameter of the image satisfies a predetermined criteria based on a first measured characteristic of the image at a first coarseness level of the plurality of coarseness levels;
determining whether the parameter of the image satisfies a predetermined criteria based on a second measured characteristic of the image at a second coarseness level of the plurality of coarseness levels; and
adjusting the parameter of the image based on a determination result of the based on the predetermined criteria.
   21. The non-transitory computer readable medium of clause 20, wherein the set of instructions that are executable by the at least one processor of the apparatus cause the apparatus to further perform analyzing the image at the plurality of coarseness levels using a plurality of image processing algorithms.
   22. The non-transitory computer readable medium of clause 20, wherein the set of instructions that are executable by the at least one processor of the apparatus cause the apparatus to further perform analyzing the image at the plurality of coarseness levels using an image processing algorithm with a plurality of parameters corresponding to the plurality of coarseness levels.
   23. The non-transitory computer readable medium of clause 22, wherein the image processing algorithm comprises a transfer function.
   24. The non-transitory computer readable medium of clause 23, wherein
the first coarseness level corresponds to a low frequency response of the transfer function, and
the second coarseness level corresponds to a high frequency response of the transfer function.
   25. The non-transitory computer readable medium of clause 22, wherein the image processing algorithm comprises a kernel.
   26. The non-transitory computer readable medium of any of clauses 20 to 25, wherein the set of instructions that are executable by the at least one processor of the apparatus cause the apparatus to further perform analyzing the image at the second coarseness level in response to determining that the parameter does not satisfy the predetermined criteria based on the first measured characteristic of the image at the first coarseness level.
   27. The non-transitory computer readable medium of any of clauses 20 to 26, wherein the set of instructions that are executable by the at least one processor of the apparatus cause the apparatus to further perform acquiring the image of the sample based on a charged particle beam generated by the charged particle beam apparatus.
   28. The non-transitory computer readable medium of clause 27, wherein the charged particle beam comprises a plurality of beamlets generated by a multi-beam apparatus.
   29. The non-transitory computer readable medium of clauses 28, wherein the set of instructions that are executable by the at least one processor of the apparatus cause the apparatus to further perform acquiring one or more images for each of a plurality of threads corresponding to each of the plurality of charged particle beamlets.
   30. The non-transitory computer readable medium of any of clauses 20 to 29, wherein the parameter is focus of the charged particle beam apparatus.
   31. The non-transitory computer readable medium of clause 20, wherein the apparatus is a tuner.
   32. The non-transitory computer readable medium of clause 20, wherein the apparatus is a calibrator.

The block diagrams in the figures illustrate the architecture, functionality, and operation of possible implementations of systems, methods, and computer hardware/software products according to various exemplary embodiments of the present disclosure. In this regard, each block in a flowchart or block diagram may represent a module, segment, or portion of code which comprises one or more executable instructions for implementing the specified logical functions. It should be understood that in some alternative implementations, functions indicated in the block may occur out of the order noted in the figures. For example, two blocks shown in succession may be executed or implemented substantially concurrently, or two blocks may sometimes be executed in reverse order, depending upon the functionality involved. It should also be understood that each block of the block diagrams, and combination of the blocks, can be implemented by special purpose hardware-based systems that perform the specified functions or acts, or by combinations of special purpose hardware and computer instructions.

It will be appreciated that the present invention is not limited to the exact construction that has been described above and illustrated in the accompanying drawings, and that various modifications and changes can be made without departing from the scope thereof.

1. A planar substrate comprising:
a plurality of first objects spaced at a first period, having a first size, and being located err throughout a first region on the substrate; and
a plurality of second objects spaced at a second period, having a second size, and being located throughout the first region,
wherein
the first size is smaller than the second size, and
the first period is smaller than the second period.

2. The substrate of claim 1, wherein the plurality of first objects comprise round shapes.

3. (canceled)

4. The substrate of claim 1, further comprising:
a plurality of third objects spaced at a third period, having a third size, and being located-throughout the first region,
wherein
the third size is larger than the second size.

5. The substrate of claim 4 wherein the first period, the second period, and the third period follow an exponentially increasing progression.

6. The substrate of claim 1, wherein the plurality of first objects and the plurality of second objects are etched in the substrate.

7. A method for adjusting a charged particle beam apparatus, comprising:
analyzing an image of a sample at a plurality of coarseness levels, the image comprising a plurality of first objects having a first feature size and a plurality of second objects having a second feature size;
determining whether a parameter of the image satisfies a predetermined criteria based on a first measured characteristic of the image at a first coarseness level of the plurality of coarseness levels;
determining whether the parameter of the image satisfies a predetermined criteria based on a second measured characteristic of the image at a second coarseness level of the plurality of coarseness levels; and
adjusting the parameter of the image based on a determination result based on the predetermined criteria.

8. The method of claim 7, wherein the image is analyzed at the plurality of coarseness levels using a plurality of image processing algorithms.

9. The method of claim 7, wherein the image is analyzed at the plurality of coarseness levels using an image processing algorithm with a plurality of parameters corresponding to the plurality of coarseness levels.

10. The method of claim 9, wherein the image processing algorithm comprises a transfer function.

11. The method of claim 10, wherein
the first coarseness level corresponds to a low frequency response of the transfer function, and
the second coarseness level corresponds to a high frequency response of the transfer function.

12. The method of claim 9, wherein the image processing algorithm comprises a kernel.

13. The method of claim 7, wherein in response to determining that the parameter does not satisfy the predetermined criteria based on the first measured characteristic of the image at the first coarseness level, the image is analyzed at the second coarseness level.

14. The method of claim 7, further comprising
acquiring the image of the sample based on a charged particle beam generated by the charged particle beam apparatus.

15. A non-transitory computer readable medium comprising a set of instructions that are executable by one or more processors of an apparatus to cause the apparatus to perform a method comprising:
acquiring analysis of an image of a sample at a plurality of coarseness levels, the image comprising a plurality of first objects having a first feature size and a plurality of second objects having a second feature size;
determining whether a parameter of the image satisfies a predetermined criteria based on a first measured characteristic of the image at a first coarseness level of the plurality of coarseness levels;
determining whether the parameter of the image satisfies a predetermined criteria based on a second measured characteristic of the image at a second coarseness level of the plurality of coarseness levels; and
adjusting the parameter of the image based on a determination result of the based on the predetermined criteria.

16. The substrate of claim 1, wherein the plurality first objects and second objects are intermixed throughout the first region.
